(19) United States
(12) Patent Application Publication
(10) Pub. No.: US 2025/0359184 A1
(43) Pub. Date: Nov. 20, 2025

(54) SEMICONDUCTOR STRUCTURE

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/893,830

(22) Filed: Sep. 23, 2024

(30) Foreign Application Priority Data
May 14, 2024 (CN) 202410598763.4

(51) Int. Cl. H01L 29/47; H01L 23/31; H01L 29/20; H01L 29/778

(52) U.S. Cl. CPC H10D 30/675; H01L 23/3171; H10D 30/475; H10D 30/6738; H10D 62/85; H10D 62/8503; H10D 64/64

(57) ABSTRACT

A semiconductor structure includes a substrate, a channel layer and a barrier layer stacked sequentially, and a P-type semiconductor layer in a gate region is configured to implement an enhancement mode device; a crystalline layer, a SiN layer and an amorphous layer stacked sequentially on the P-type semiconductor layer, where the crystalline layer forms a junction with the P-type semiconductor layer, so that injection of carriers is blocked, and leakage current is reduced. The crystalline layer enhances polarization, a hole concentration of the P-type semiconductor layer is induced to increase, and a threshold voltage of the device is improved. In addition, when a voltage is applied to the gate, a uniform electric field distribution may be formed in the gate region, and a probability that the device is broken down is reduced. The amorphous layer may reduce leakage.

### CROSS-REFERENCE TO RELATED APPLICATIONS

The present disclosure claims priority to Chinese Patent Application No. 202410598763.4, filed on May 14, 2024, all contents of which are incorporated herein in its entirety by reference.

### TECHNICAL FIELD

The present disclosure relates to the field of semiconductor technologies, in particular, to a semiconductor structure.

### BACKGROUND

Compared with a first-generation semiconductor material and a second-generation semiconductor material, a third-generation semiconductor material, especially a GaN-based material (gallium nitride) has advantages of wide band gap, high breakdown field strength, high electron mobility, strong radiation resistance and the like. The GaN-based High Electron Mobility Transistor (HEMT) device has great development potential in high-frequency and high-power fields such as wireless communication base stations, radars, automobile electronics, and the like.

In general, the GaN-based HEMT device is a depletion mode field effect transistor, for example, a negative turn-on voltage needs to be used in a radio frequency microwave application, which makes a circuit structure become complex and the anti-misoperation protection function of the circuit is also affected, reducing a safety of the circuit, and therefore, it is necessary to carry out a research on an enhancement mode GaN-based HEMT device. The P-type gate is adopted in a conventional GaN-based HEMT device to achieve enhancement mode, but there are still many problems such as a large gate leakage current.

### SUMMARY

In view of this, embodiments of the present disclosure provide a semiconductor structure to solve technical problems of large gate leakage current and low breakdown voltage in the prior art.

According to a first aspect, a semiconductor structure is provided, the semiconductor includes: a substrate, a channel layer and a barrier layer stacked sequentially, where the channel layer and the barrier layer include a gate region, a source region located at a side of the gate region and a drain region located at another side of the gate region, where the gate region includes: a P-type semiconductor layer, a crystalline layer, a SiN layer, an amorphous layer and a gate stacked sequentially at a side, away from the substrate, of the barrier layer; and a source and a drain, where the source is located on the source region, and the drain is located on the drain region.

In an embodiment, a material of the crystalline layer includes a crystalline AlN; and/or a material of the amorphous layer includes an amorphous AlN.

In an embodiment, the crystalline AlN is a monocrystalline AlN or a polycrystalline AlN.

In an embodiment, the crystalline layer, the SiN layer and the amorphous layer at least cover a part of a sidewall of the P-type semiconductor layer.

In an embodiment, the semiconductor further includes: a passivation layer located between the crystalline layer and the barrier layer, where the passivation layer is located between the gate region and the source region and between the gate region and the drain region.

In an embodiment, the crystalline layer, the SiN layer and the amorphous layer are located above the passivation layer.

In an embodiment, the P-type semiconductor layer has a portion of epitaxial lateral overgrowth and covers a part of the passivation layer.

In an embodiment, the crystalline layer, the SiN layer and the amorphous layer are located between the gate region and the source region, and are also located between the gate region and the drain region.

In an embodiment, the crystalline layer, the SiN layer and the amorphous layer include via holes, and the gate is in contact with the P-type semiconductor layer through the via holes.

In an embodiment, the via holes are arranged periodically.

In an embodiment, a three-dimensional shape of the via holes is a cube, a cylinder, a cone or a frustum.

In an embodiment, a thickness of the P-type semiconductor layer is greater than a thickness of the crystalline layer.

In an embodiment, a thickness ratio of the P-type semiconductor layer to the crystalline layer ranges from 2 to 20.

In an embodiment, a thickness of the crystalline layer is greater than a thickness of the SiN layer; and/or, a thickness of the amorphous layer is greater than the thickness of the SiN layer.

In an embodiment, a thickness ratio of the crystalline layer to the SiN layer ranges from 2 to 10; and/or, a thickness ratio of the amorphous layer to the SiN layer ranges from 2 to 10.

In an embodiment, a thickness of the crystalline layer is equal to a thickness of the amorphous layer.

In an embodiment, a thickness of the crystalline layer is less than or equal to 80 nm.

In an embodiment, a band gap of the amorphous layer is greater than a band gap of the P-type semiconductor layer.

In an embodiment, a band gap of the crystalline layer is greater than a band gap of the P-type semiconductor layer.

In an embodiment, a band gap of the amorphous layer is greater than a band gap of the SiN layer, and a band gap of the crystalline layer is greater than a band gap of the SiN layer.

### BRIEF DESCRIPTION OF THE DRAWINGS

FIG. 1 is a schematic structural diagram of a semiconductor structure according to an embodiment of the present disclosure.

FIG. 2 is a schematic structural diagram of another semiconductor structure according to an embodiment of the present disclosure.

FIG. 3 is a schematic structural diagram of another semiconductor structure according to an embodiment of the present disclosure.

FIG. 4 is a schematic structural diagram of another semiconductor structure according to an embodiment of the present disclosure.

FIG. 5 is a schematic structural diagram of another semiconductor structure according to an embodiment of the present disclosure.

### DETAILED DESCRIPTION OF THE EMBODIMENTS

Technical solutions in the embodiments of the present disclosure will be clearly described below with reference to the accompanying drawings in the embodiments of the present disclosure. Apparently, the described embodiments are a part of the embodiments of the present disclosure, rather than all the embodiments.

In order to solve the problem of a large gate leakage current, the present disclosure provides a semiconductor structure. The following further illustrates the semiconductor structure mentioned in the present disclosure with reference to FIG. 1 to FIG. 5.

FIG. 1 is a schematic structural diagram of a semiconductor structure according to an embodiment of the present disclosure. As shown in FIG. 1, the semiconductor includes: a substrate 10, a channel layer 20 and a barrier layer 30 stacked sequentially, and the channel layer 20 and the barrier layer 30 include a gate region 40a, a source region 40b located at a side of the gate region 40a and a drain region 40c located at another side of the gate region 40a; the gate region 40a includes a P-type semiconductor layer 51, a crystalline layer 601, a SiN layer 602, an amorphous layer 603 and a gate 41 stacked sequentially at a side, away from the substrate 10, of the barrier layer 30; and a source 42 and a drain 43, the source 42 is located on the source region 40b, and the drain 43 is located on the drain region 40c.

Specifically, as shown in FIG. 1, the channel layer 20 and the barrier layer 30 form a heterojunction, and a channel of two-dimensional electron gas (2DEG) is formed on a surface, close to the barrier layer 30, of the channel layer 20. When no voltage is applied to a semiconductor device, the 2DEG in the channel may be depleted by the P-type semiconductor layer 51, so as to implement an enhancement mode device. Specifically, in the gate region 40a, the crystalline layer 601, the SiN layer 602 and the amorphous layer 603 are disposed at a side, away from the substrate 10, of the P-type semiconductor layer 51. Firstly, the crystalline layer 601 forms a junction with the P-type semiconductor layer 51, so that injection of carriers is blocked, and leakage current is reduced. Secondly, the crystalline layer 601 enhances polarization, a hole concentration of the P-type semiconductor layer 51 is induced to increase, and a threshold voltage of the device is improved. When a voltage is applied to the gate, a uniform electric field distribution may be formed in the gate region, and a probability that the device is broken down is reduced. The amorphous layer 603 may reduce leakage. In order to improve a stability of the crystalline state of the crystalline layer 601 and the amorphous layer 603, the SiN layer 602 is disposed between the crystalline layer 601 and the amorphous layer 603. Additionally, the SiN layer 602 may reduce the leakage current. Therefore, a three-layer reinforced layer is disposed on the P-type semiconductor layer 51 of the semiconductor structure, and the three-layer reinforced layer includes the crystalline layer, the SiN layer and the amorphous layer. By controlling a crystalline state of the amorphous layer and the crystalline layer, the gate leakage current may be reduced, and the breakdown voltage of the device may be improved.

Optionally, a material of the substrate 10 is selected from any one of monocrystalline silicon, monocrystalline germanium, sapphire, diamond, SiC and GaN.

Optionally, a GaN-based semiconductor material is used in the semiconductor structure, for example, a material of the channel layer 20 is GaN, and a material of the barrier layer 30 is AlGaN.

In an embodiment, a material of the crystalline layer 601 includes crystalline AlN; and/or a material of the amorphous layer includes an amorphous AlN. Specifically, the crystalline layer 601 and the amorphous layer 603 use AlN materials with different crystalline states. The crystalline layer 601 uses the crystalline AlN, which has a large band gap, so as to further enhance polarization, and the hole concentration of the P-type semiconductor layer is induced to increase, thereby improving the threshold voltage of the device. When a voltage is applied to the gate, a uniform electric field distribution may be formed in the gate region, and a probability that the device is broken down is reduced. The amorphous layer uses the amorphous AlN, which has a large band gap, so as to increase the Schottky barrier height between the gate 41 and the P-type semiconductor layer 51, thereby improving the breakdown voltage.

Optionally, a band gap of the amorphous layer 603 is greater than a band gap of the P-type semiconductor layer 51, so as to increase the Schottky barrier height between the gate 41 and the P-type semiconductor layer 51, thereby improving the breakdown voltage.

Optionally, a material of the crystalline layer 603 is the crystalline AlN, the crystalline AlN is a monocrystalline AlN or a polycrystalline AlN. and a crystal arrangement of the monocrystalline AlN is more uniform. Therefore, a relatively uniform electric field distribution is formed in the gate region, thereby further reducing a probability that the device is broken down.

Optionally, a material with a large band gap is selected to make the crystalline layer 601, the band gap of the crystalline layer 601 is greater than the band gap of the P-type semiconductor layer 51, and the crystalline layer 601 forms a junction with the p-type semiconductor layer 51, so that the injection of carriers may be blocked, and the gate leakage current is reduced.

Optionally, a band gap of the amorphous layer 603 is greater than a band gap of the SiN layer 602, and a band gap of the crystalline layer 601 is greater than a band gap of the SiN layer 602, so as to reduce the gate forward current.

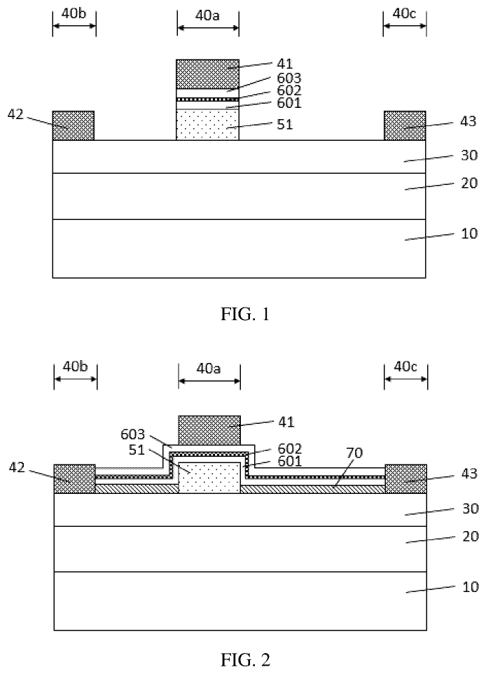

In an embodiment, FIG. 2 is a schematic structural diagram of another semiconductor structure according to an embodiment of the present disclosure. As shown in FIG. 2, the crystalline layer 601, the SiN layer 602 and the amorphous layer 603 at least cover a part of a sidewall of the P-type semiconductor layer 51. Specifically, in a cross-section shown in FIG. 2, the amorphous layer 601, the SiN layer 602 and the crystalline layer 603 cover an upper surface of the P-type semiconductor layer 51 and a part of a sidewall of the P-type semiconductor layer 51, so as to reduce the leakage current and improve the reliability of the device.

It should be noted that, as shown in FIG. 2, the semiconductor structure further includes a passivation layer 70, the passivation layer 70 is located between the gate region 40a and the source region 40b and between the gate region 40a and the drain region 40c, and the passivation layer 70 is located between the crystalline layer 601 and the barrier layer 30. Optionally, a material of the passivation layer 70 is SiN or SiO₂.

It should be noted that, as shown in FIG. 2, the amorphous layer 601, the SiN layer 602 and the crystalline layer 603 are located above the passivation layer 70, the amorphous layer 601, the SiN layer 602 and the crystalline layer 603 that are located between the gate region 40a and the source region 40b and between the gate region 40a and the drain region 40c are not etched, thereby reducing an etching damage and improving the reliability of the device.

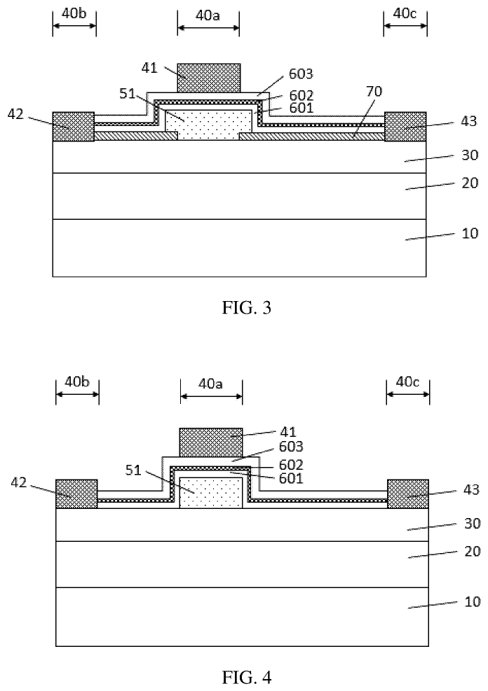

Specifically, the passivation layer 70 with an opening is formed on the barrier layer 30, the P-type semiconductor layer 51 is formed at the opening by a secondary epitaxy, and then the crystalline layer 601, the SiN layer 602 and the amorphous layer 603 are deposited to cover the P-type semiconductor layer 51. Optionally, FIG. 3 is a schematic structural diagram of another semiconductor structure according to an embodiment of the present disclosure. As shown in FIG. 3, the P-type semiconductor layer 51 is has a portion of epitaxial lateral overgrowth and covers a part of the passivation layer 70, and a part of the P-type semiconductor layer 51 that uses lateral epitaxy may alleviate the electric field intensity near the gate region, thereby improving the breakdown voltage of the device.

In an embodiment, FIG. 4 is a schematic structural diagram of another semiconductor structure according to an embodiment of the present disclosure. As shown in FIG. 4, the crystalline layer 601, the SiN layer 602 and the amorphous layer 603 are located between the gate region 40a and the source region 40b, and are also located between the gate region 40a and the drain region 40c. Specifically, the crystalline layer 601, the SiN layer 602, and the amorphous layer 603 are entirely deposited on a side, away from the substrate 10, of the barrier layer 30 and the P-type semiconductor layer 51. Subsequently, the crystalline layer 601, the SiN layer 602, and the amorphous layer 603 that are located in the source region 40b and the drain region 40c are only etched, and positions for the formation of the source 42 and the drain 43 are reserved, thereby avoiding the deterioration of the power characteristics of the device caused by over-etched the barrier layer 30.

It should be noted that, comparing FIG. 2 and FIG. 4, the passivation layer 70 is added between the barrier layer 30 and the crystalline layer 601 in FIG. 2.

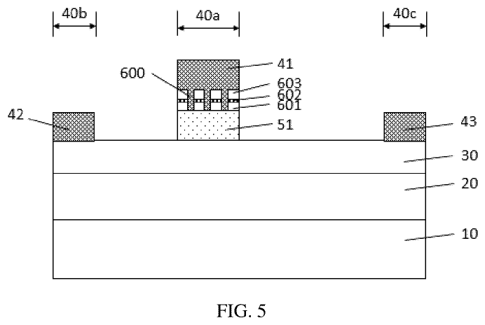

In an embodiment, FIG. 5 is a schematic structural diagram of another semiconductor structure according to an embodiment of the present disclosure. As shown in FIG. 5, the crystalline layer 601, the SiN layer 602 and the amorphous layer 603 include via holes 600, and the gate 41 is in contact with the P-type semiconductor layer 51 by the via holes 600. Specifically, by controlling a ratio of an area of the via holes 600 to the gate region 40a, a contact area between the gate 41 and the P-type semiconductor layer 51 may be controlled, thereby controlling a range of the gate voltage. It may be understood that the smaller an area of the via holes 600 relative to an area of the gate region 40a, the larger a range of the gate voltage. Therefore, by properly increasing the area of the via holes 600 may reduce the range of the gate voltage, thereby reducing a risk that the device is broken down and improving the reliability of the device.

Optionally, the via holes 600 are arranged periodically. In other words, the gate region 40 at a per unit area has the via holes 600 of the same area, so that a voltage at the per unit area of the gate region remains consistent, thereby further reducing the risk that the device is broken down. Optionally, in a direction perpendicular to the substrate 10, a three-dimensional shape of the via holes 600 is a cube, a cylinder, a cone, or a frustum.

In an embodiment, a thickness of the P-type semiconductor layer 51 is greater than a thickness of the crystalline layer 601. Specifically, the thickness of the crystalline layer 601 is reduced, so as to avoid affecting the gate control capability. The thickness of the crystalline layer 601 is increased properly, so that the hole concentration of the P-type semiconductor layer is induced to increase, and the threshold voltage of the device is improved.

Optionally, a thickness ratio of the P-type semiconductor layer 51 to the crystalline layer 601 ranges from 2 to 20, that is, the thickness of the p-type semiconductor layer 51 is 2 to 20 times the thickness of the crystalline layer 601.

Optionally, the thickness of the crystalline layer 601 is less than or equal to 80 nm. Optionally, the thickness of the P-type semiconductor layer 51 is between 40 nm and 240 nm.

In an embodiment, a thickness of the crystalline layer 601 is greater than a thickness of the SiN layer 602; and/or a thickness of the amorphous layer 603 is greater than a thickness of the SiN layer 602. Specifically, firstly, a thinner SiN layer 602 may stabilize the crystalline state of the crystalline layer 601 and the amorphous layer 603, and avoid the reduction of the gate control capability due to excessive thickness of the amorphous layer 601, the SiN layer 602 and the crystalline layer 603, so the thickness of the SiN layer 602 may be appropriately reduced. Secondly, the thickness of the crystalline layer 601 and the amorphous layer 603 is appropriately increased to facilitate control to form different the crystalline states.

Optionally, a thickness ratio of the crystalline layer 601 to the SiN layer 602 ranges from 2 to 10, that is, the thickness of the crystalline layer 601 is 2 to 10 times the thickness of the SiN layer 602; and/or, a thickness ratio of the amorphous layer 603 to the SiN layer 602 ranges from 2 to 10, that is, the thickness of the amorphous layer 603 is 2 to 10 times the thickness of the SiN layer 602.

Optionally, the thickness of the crystalline layer 601 is equal to the thickness of the amorphous layer 603.

The semiconductor structure provided in the embodiments of the disclosure includes a substrate, a channel layer and a barrier layer sequentially stacked, and the channel layer and the barrier layer form a heterojunction. When no voltage is applied to a semiconductor device, the 2DEG in the channel may be depleted by the P-type semiconductor layer, so as to implement an enhancement mode device; a crystalline layer, a SiN layer and an amorphous layer are stacked sequentially on the P-type semiconductor layer, and the crystalline layer forms a junction with the P-type semiconductor layer, so that injection of carriers is blocked, and leakage current is reduced. Secondly, the crystalline layer enhances polarization, the hole concentration of the P-type semiconductor layer is induced to increase, and the threshold voltage of the device is improved. In addition, when a voltage is applied to the gate, a uniform electric field distribution may be formed in the gate region, and a probability that the device is broken down is reduced. The amorphous layer may reduce leakage. The SiN layer is located between the crystalline layer and the amorphous layer, and a stability of the crystalline state of the crystalline layer and the amorphous layer may be improved.

It should be understood that the terms “include” and variations thereof used in the present disclosure are open ended, that is, “including but not limited to”. The term “an embodiment” means “at least one embodiment”. In this specification, specific features, structures, materials, or characteristics described may be combined in any suitable manner in any one or more embodiments or examples. In addition, in the case of no contradiction, a person skilled in the art may combine and integrate different embodiments or examples described in this specification, as well as features of different embodiments or examples.

What is claimed is:

1. A semiconductor structure, comprising:
a substrate, a channel layer and a barrier layer stacked sequentially, wherein the channel layer and the barrier layer comprise a gate region, a source region located at a side of the gate region and a drain region located at another side of the gate region; the gate region comprises: a P-type semiconductor layer, a crystalline layer, a SiN layer, an amorphous layer and a gate stacked sequentially at a side, away from the substrate, of the barrier layer; and
a source and a drain, wherein the source is located on the source region, and the drain is located on the drain region.

2. The semiconductor structure according to claim 1, wherein a material of the crystalline layer comprises a crystalline AlN, and/or, a material of the amorphous layer comprises an amorphous AlN.

3. The semiconductor structure according to claim 2, wherein the crystalline AlN is a monocrystalline AlN or a polycrystalline AlN.

4. The semiconductor structure according to claim 1, wherein the crystalline layer, the SiN layer and the amorphous layer at least cover a part of a sidewall of the P-type semiconductor layer.

5. The semiconductor structure according to claim 1, further comprising: a passivation layer located between the crystalline layer and the barrier layer, wherein the passivation layer is located between the gate region and the source region and between the gate region and the drain region.

6. The semiconductor structure according to claim 5, wherein the crystalline layer, the SiN layer and the amorphous layer are located above the passivation layer.

7. The semiconductor structure according to claim 5, wherein the P-type semiconductor layer has a portion of epitaxial lateral overgrowth and covers a part of the passivation layer.

8. The semiconductor structure according to claim 1, wherein the crystalline layer, the SiN layer and the amorphous layer are located between the gate region and the source region, and are also located between the gate region and the drain region.

9. The semiconductor structure according to claim 1, wherein the crystalline layer, the SiN layer and the amorphous layer comprise via holes, and the gate is in contact with the P-type semiconductor layer through the via holes.

10. The semiconductor structure according to claim 9, wherein the via holes are arranged periodically.

11. The semiconductor structure according to claim 9, wherein a three-dimensional shape of the via holes is a cube, a cylinder, a cone or a frustum.

12. The semiconductor structure according to claim 1, wherein a thickness of the P-type semiconductor layer is greater than a thickness of the crystalline layer.

13. The semiconductor structure according to claim 12, wherein a thickness ratio of the P-type semiconductor layer to the crystalline layer ranges from 2 to 20.

14. The semiconductor structure according to claim 1, wherein a thickness of the crystalline layer is greater than a thickness of the SiN layer; and/or, a thickness of the amorphous layer is greater than the thickness of the SiN layer.

15. The semiconductor structure according to claim 14, wherein a thickness ratio of the crystalline layer to the SiN layer ranges from 2 to 10; and/or, a thickness ratio of the amorphous layer to the SiN layer ranges from 2 to 10.

16. The semiconductor structure according to claim 1, wherein a thickness of the crystalline layer is equal to a thickness of the amorphous layer.

17. The semiconductor structure according to claim 1, wherein a thickness of the crystalline layer is less than or equal to 80 nm.

18. The semiconductor structure according to claim 1, wherein a band gap of the amorphous layer is greater than a band gap of the P-type semiconductor layer.

19. The semiconductor structure according to claim 1, wherein a band gap of the crystalline layer is greater than a band gap of the P-type semiconductor layer.

20. The semiconductor structure according to claim 1, wherein a band gap of the amorphous layer is greater than a band gap of the SiN layer, and a band gap of the crystalline layer is greater than a band gap of the SiN layer.
